(19) United States
(12) Patent Application Publication
(10) Pub. No.: US 2006/0156097 A1
(43) Pub. Date: Jul. 13, 2006

(54) Analog counter using memory cell

(76) Inventors: Christian A. Camarce, Sacramento, CA (US); Gerald J. Barkley, Oregon, WI (US); Hernan A. Castro, Shingle Springs, CA (US); Kerry D. Tedrow, Folsom, CA (US)

Correspondence Address: TROP PRUNER & HU, PC, 8554 KATY FREEWAY, SUITE 100, HOUSTON, TX, 77024, US

(21) Appl. No.: 10/999,598

(22) Filed: Nov. 30, 2004

(51) Int. Cl. G01R 31/28

(52) U.S. Cl. 714/724

(57) ABSTRACT

A non-volatile memory may include at least one cell that functions as an analog counter. In one embodiment, the counter may count the number of cycles experienced by the memory and provide an indication when a predetermined number of cycles have been completed. The completion of the given number of cycles may indicate a reliability issue.

### BACKGROUND

This invention relates generally to semiconductor memories such as flash memories.

In non-volatile memory design, stringent cycling requirements may pose reliability issues. Generally, a cycle is one program and one erase operation. For instance, a memory may be specified to operate properly through a 100,000 cycles. This means the component must be able to be programmed and erased reliably 100,000 times.

As a part is cycled, many intrinsic properties of the memory degrade, including the minimum drain voltage needed to program the cell. After 100,000 cycles, the minimum drain voltage of the cell is much higher than at zero cycles. On the other hand, there is also a maximum drain voltage that can be applied during programming without disturbing the memory cell. Like the minimum drain voltage, the maximum drain voltage also degrades over cycling. The region between the maximum drain voltage and the minimum drain voltage, that determines the cell's drain voltage during programming, can be called program drain window. So, over cycling, the program drain window is positive in order for the non-volatile memory to program reliably.

As non-volatile memory cells decrease in size, intrinsic properties of the memory cell also become worse than with previous technologies. One property that degrades is the minimum drain voltage of the cell. Since the minimum voltage at time zero is typically set to the minimum drain voltage at a specified lifetime cycle count, the program drain window may be at a deficit. For example, the minimum drain voltage at zero cycles may be higher than the maximum drain voltage at zero cycles. Thus, it would be useful to know how many times a given device has been cycled.

Thus, there is a need for ways to monitor non-volatile memories over their useful life.

### BRIEF DESCRIPTION OF THE DRAWINGS

FIG. 1 is a schematic depiction of one embodiment of the present invention when the counter is being incremented;

FIG. 2 is a schematic depiction corresponding to FIG. 1, but after the counter has been incremented and at the time when a check is being done to determine whether the pre-programmed count has been reached;

FIG. 3 is a flow chart for software according to one embodiment of the present invention;

FIG. 4 is a hypothetical graph of threshold voltage versus number of 500 nanosecond pulses for illustration purposes;

FIG. 5 is a schematic depiction of a portion of a non-volatile memory array in accordance with one embodiment of the present invention; and

FIG. 6 is a system depiction of one embodiment of the present invention.

### DETAILED DESCRIPTION

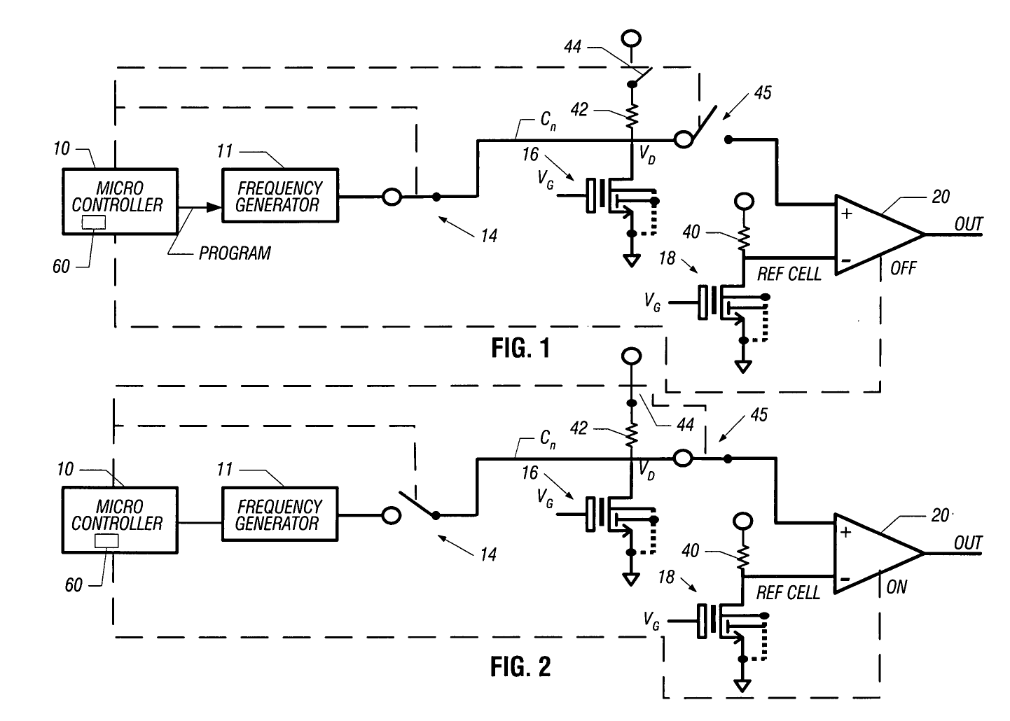

Referring to FIG. 1, an analog counter for a non-volatile semiconductor memory block (not shown) may use a microcontroller 10 that may store instructions or code 60. The microcontroller 10 may be hardwired to implement the code 60 in another embodiment. When the microcontroller 10 detects a bit sequence indicative that a command to erase a block of non-volatile memory has been issued, the microcontroller 10 may issue a program pulse, as indicated, to a frequency generator 11. Other technologies for detecting a cycle may also be used.

Generally, in many non-volatile semiconductor memories and, particularly, in flash memories, a block erase may be implemented, where instead of selectively erasing some cells, an entire block of cells is erased and then rewritten with the correct information. In order to determine the number of cycles which the block undergoes, it may be desirable, in one embodiment, to determine when a block erase has been ordered.

Thus, each time an erase is ordered, the program pulse may be provided to the frequency generator 11. In one embodiment, the frequency generator 11 may be a delay chain or string of inverters. In another embodiment, it may be a ring oscillator. The frequency generator 11 produces a pulse of the desired pulse width, such as 500 nanoseconds, each time an erase command is issued or detected by the microcontroller 10 in one embodiment of the present invention.

If the switch 14 is in its closed position, as indicated in FIG. 1, the pulse that is generated by the frequency generator 11 is applied to the drain of an analog counter 16. In one embodiment, the analog counter 16 is a memory cell associated with the non-volatile semiconductor memory block. The non-volatile semiconductor memory may be subject to the problems, described above, with respect to reliability degradation after a certain number of memory cycles. Thus, the counter 16 may keep track of the number of times that a block of memory is cycled.

In one embodiment, the counter 16 may be in an otherwise unused row of memory cells associated with the block. For example, in some memories, one or more rows along the edge of the integrated circuit semiconductor memory may never be utilized. An unused row of this type, which may be called a dummy row, may be utilized to implement an analog counter in accordance with some embodiments of the present invention. In such case, an otherwise unused memory row may be utilized to implement an analog counter. Thus, when X counters 16 in an unused memory row are used, each counter counting to N, a total count of X times N, can be detected.

In one embodiment, the counter 16 is a flash memory cell. It has a gate voltage, indicated as V_{G}, which may also correspond to a row voltage, and a drain voltage, indicated as V_{D}, which may correspond to a column voltage. Typically, the counter 16 has its drain, gate, and source biased to place the device in saturation mode. That is, the drain-to-source voltage potential is greater than or equal to the gate-to-source voltage potential minus the threshold voltage of the transistor.

The counter 16 may have a p-well and the n-well connected as indicated. The source may be coupled to ground. Typically, to program the counter 16, the p and n-wells are connected to the source terminal which is tied to ground.

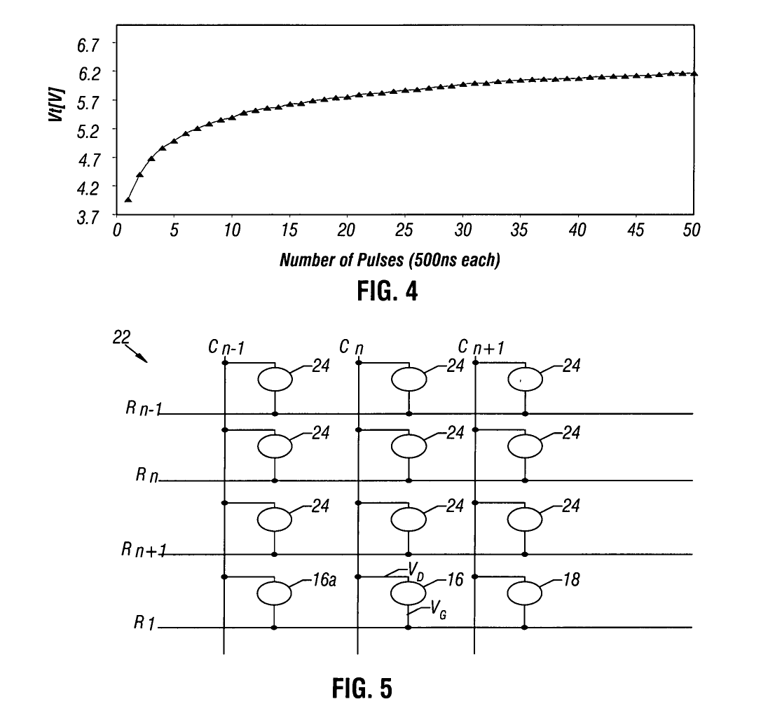

With constant drain, gate, and source voltage applied to the cell, its threshold increases over time. This is shown in FIG. 4. As more and more programming pulses are progressively applied to a non-volatile semiconductor memory cell, its threshold voltage increases. Thus, when the counter 16 reaches a given threshold, the number of pulses of uniform pulse width that have been applied to the cell may be determined from its threshold voltage.

Referring again to FIG. 1, the drain of the counter 16 is coupled to a resistor 42 and a switch 44, which is open, but would otherwise be coupled to a supply voltage. Thus, during programming, the counter 16 is cutoff from the power supply by the switch 44. The counter 16 is also cutoff from the comparator 20 by the switch 45.

The comparator 20 is coupled to a reference cell 18. In one embodiment of the present invention, the reference cell 18 is another flash memory cell in the same row with the counter 16. It may be preprogrammed to a desired threshold level. Then, when the comparator 20 determines that the threshold voltage of the counter 16 and reference cell 18 are the same, the number of constant width pulses seen by the counter 16 may be determined. In one embodiment, this count corresponds to the number of cycles experienced by a memory block associated with the counter 16.

To facilitate programming of the reference cell 18, in some embodiments, instead of programming it with the number of pulses which equal the desired count to be detected on the counter 16, the cell 18 may be programmed with fewer pulses of greater width.

In the embodiment depicted in FIG. 1, when the counter 16 is being incremented as a result of an erase detection, the comparator 20 may be turned off as indicated. In some embodiments, the microcontroller 10 may control the switches 14, 44, 45, and can also control the application of power to the comparator 20.

The frequency generator 11 may program the counter 16 after an erase has already been completed on the other cells in a block that includes the counter 16. During the erase cycle for the other cells in the block, the counter 16 and the reference cell 18 are not erased. If they were erased, they would lose the count and the reference level needed to determine when the counter 16 reaches the desired count. After the desired count or threshold voltage has been reached, then the reference cell 18 and the counter 16 may be erased in some cases.

Referring to FIG. 2, after programming the counter 16 as a result of another cycle, a check may be done to determine whether or not the counter 16 has reached its predetermined count or threshold voltage. Again, the predetermined count may correspond to a given number of cycles which the block has experienced to a point where the block may no longer be fully reliable.

To make this determination, the switch 14 is opened, the switch 44 is closed, the switch 45 is closed, and the comparator 20 is turned on. As a result, the threshold voltage of the counter 16 can be compared to the threshold voltage of the preprogrammed reference cell 18.

Referring to FIG. 5, the block 22 may include columns Cn−₁ to Cn+₁ and rows Rn+₁ to Rn−₁. Of course, a memory block would have many more rows and columns than what is depicted. The rows and columns connect to memory cells 24. An unused row R₁ may have a cell 16a, which in the embodiment depicted may be unused, the counter 16, and the reference cell 18.

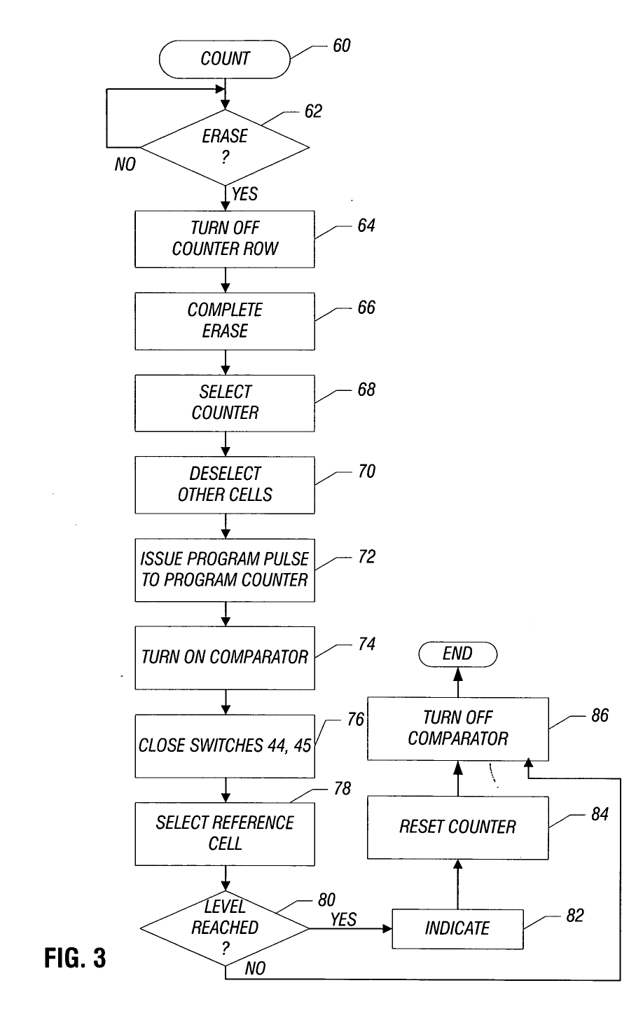

Referring to FIG. 3, the code 60, which in one embodiment may be stored on the microcontroller 10, begins by determining whether an erase command has been issued as indicated in diamond 62. This may be determined by detecting a bit sequence indicative of an erase. If so, the row R₁ that includes the counter 16 and the reference cell 18 may be turned off as indicated in block 64. While that row R₁ is turned off, the erase is completed (block 66) for the rest of the rows and columns in the block 22 that includes the row R₁.

To erase the other cells, their gates are biased negatively to repel charge off their floating gates in a flash memory embodiment. At this time, the counter row R₁ may be turned off by applying zero or positive volts to the row R₁.

Then, the counter 16 may be selected as indicated in block 68. The selection may be implemented by the switch 14 in particular and by the application of the gate voltage to the row R₁. At this point, after an erase has occurred, the other cells in the block may be deselected as indicated in block 70.

Then, the program pulse may be issued by the microcontroller 10 to the frequency generator 11 as indicated in block 72. At the same time, the gate of the counter 16 goes positive to attract electrons onto the floating gate and to continue to increase the threshold voltage of the counter 16, for example, according to the characteristic curve illustrated in FIG. 4.

Then, the comparator 20 is turned on as indicated in block 74. The switches 44 and 45 are closed as indicated in block 76. The reference cell 18 is selected, as indicated in block 78, by turning on its gate voltage.

A check at diamond 80 determines whether the threshold voltage of the counter 16 equals that of the reference cell 18, indicating that the predetermined count has been reached. If so, an indication is provided (block 82). The indication may be an alert that may be issued to a system by the memory that includes the counter 16. Next, the counter 16 may be erased or reset, as indicated in block 84, in some embodiments. Then the comparator 20 is turned off as indicated in block 86.

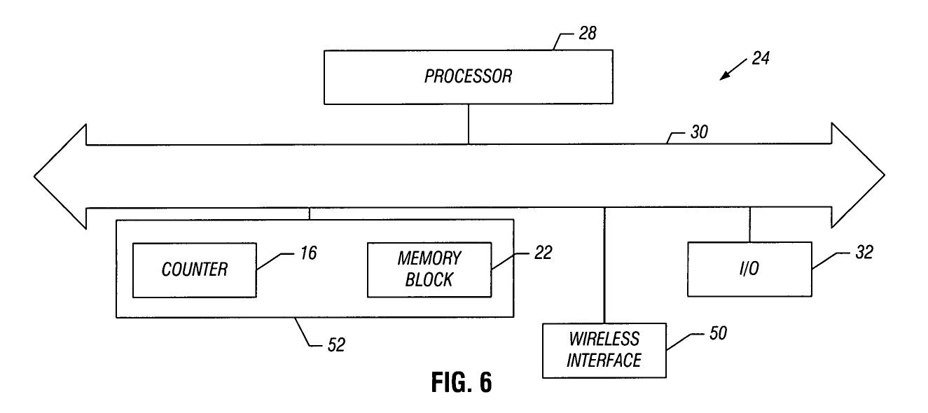

Turning to FIG. 6, a portion of a system 24, in accordance with an embodiment of the present invention, is described. System 24 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 24 may be used in any of the following systems: a wireless local area network (WLAN) system, a wireless personal area network (WPAN) system, or a cellular network, although the scope of the present invention is not limited in this respect.

System 24 may include a controller or processor 28, an input/output (I/O) device 32 (e.g. a keypad, display), a memory 52, a wireless interface 50, and a static random and coupled to each other via a bus 30. The memory 52 may include the counter 16 and its associated block 22. It should be noted that the scope of the present invention is not limited to embodiments having any or all of these components.

Processor 28 may comprise, for example, one or more microprocessors, digital signal processors, micro-controllers, or the like. Memory 52 may be used to store messages transmitted to or by system 24. Memory 52 may also optionally be used to store instructions that are executed by processor 28 during the operation of system 24, and may be used to store user data. The instructions may be stored as digital information and the user data, as disclosed herein, may be stored in one section of the memory as digital data and in another section as analog memory. As another example, a given section at one time may be labeled as such and store digital information, and then later may be relabeled and reconfigured to store analog information. Memory 52 may be provided by one or more different types of memory. For example, memory 52 may comprise a volatile memory (any type of random access memory), a non-volatile memory such as a flash memory.

The I/O device 32 may be used to generate a message. The system 24 may use the wireless interface 50 to transmit and receive messages to and from a wireless communication network with a radio frequency (RF) signal. Examples of the wireless interface 50 may include an antenna, or a wireless transceiver, such as a dipole antenna, although the scope of the present invention is not limited in this respect. Also, the I/O device 32 may deliver a voltage reflecting what is stored as either a digital output (if digital information was stored), or it may be analog information (if analog information was stored).

While an example in a wireless application is provided above, embodiments of the present invention may also be used in non-wireless applications as well.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. a non-volatile memory comprising:
a counter to count the number of cycles experienced by at least a portion of said memory.

2. The memory of claim 1 wherein said memory is a flash memory.

3. The memory of claim 2 wherein said counter is a flash memory cell.

4. The memory of claim 3 wherein said counter is implemented on an otherwise unused row of said memory.

5. The memory of claim 4 including a reference cell.

6. The memory of claim 5 including a comparator to compare the threshold voltage of the reference cell to the threshold voltage of said counter.

7. The memory of claim 6 wherein said counter and said reference cell are on the same row.

8. The memory of claim 6 wherein said reference cell is a flash memory that has been preprogrammed to a particular threshold voltage.

9. The memory of claim 1 including a frequency generator to generate a pulse each time that a portion of said memory is erased.

10. The memory of claim 9 wherein said frequency generator to generate a pulse to program the counter each time a block of said memory is block erased.

11. The memory of claim 1 including a microcontroller to detect an erase cycle in said memory.

12. The memory of claim 11 wherein said microcontroller to detect a bit sequence indicative of an erase cycle.

13. A method comprising:
using a cell of a memory array to count the number of times that the memory is cycled.

14. The method of claim 13 including using a flash memory cell to count the number of times the memory is cycled.

15. The method of claim 13 including counting the number of times that a flash memory is block erased.

16. The method of claim 15 including counting the number of times that a block of flash memory is block erased using a flash memory cell associated with said block.

17. The method of claim 16 including using a cell in an unused row of flash memory to count the number of times that a block is block erased.

18. The method of claim 13 including comparing the threshold voltage of a reference cell to the threshold voltage of a cell that is programmed on each memory cycle to determine the number of memory cycles.

19. The method of claim 13 including detecting an erase command.

20. The method of claim 19 including, in response to the detection of an erase command, issuing a program pulse to a memory cell to program said memory cell.

21. The method of claim 20 including increasing the threshold voltage of the memory cell by programming the memory cell in response to the memory being cycled.

22. The method of claim 13 including preventing the erasing of a memory cell used to count the number of times that the memory is cycled.

23. An article comprising a machine accessible medium including instructions that, if executed, enable a processor-based system to:
count the number of times that a memory is cycled.

24. The article of claim 23 further including instructions that, if executed, enable a processor-based system to count the number of times that a flash memory is block erased.

25. The article of claim 23 further including instructions that, if executed, enable the threshold voltage of a reference cell to be compared to the threshold voltage of a cell that is programmed on each memory cycle to determine the number of memory cycles.

26. The article of claim 23 further including instructions that, if executed, enable the processor-based system to detect an erase command.

27. The article of claim 26 further including instructions that, if executed, enable the processor-based system to issue a program pulse to a memory cell to program said memory cell in response to the detection of an erase command.

28. The article of claim 23 further including instructions that, if executed, prevent the erasing of a memory cell used to count the number of times that a memory is cycled.

29. A system comprising:
a processor;
a wireless interface coupled to said processor;
a non-volatile memory coupled to said processor; and
a counter to count the number of cycles experienced by at least a portion of said memory.

30. The system of claim 29 wherein said memory is a flash memory.

31. The system of claim 30 wherein said counter is a flash memory cell.

32. The system of claim 31 wherein said counter is implemented on an otherwise unused row of said memory.

33. The system of claim 32 including a reference cell.

34. The system of claim 33 including a comparator to compare the threshold voltage of the reference cell to the threshold voltage of said counter.

35. The system of claim 34 wherein said counter and said reference cell are on the same row.

36. The system of claim 34 wherein said reference cell is a flash memory that has been preprogrammed to a particular threshold voltage.

37. The system of claim 29 including a frequency generator to generate a pulse each time that a portion of said memory is erased.

38. The system of claim 37 wherein said frequency generator to generate a pulse to program the counter each time a block of said memory is block erased.

39. The system of claim 29 including a microcontroller to detect an erase cycle in said memory.

40. The system of claim 11 wherein said microcontroller to detect a bit sequence indicative of an erase cycle.
